(19) United States
(12) Patent Application Publication
(10) Pub. No.: US 2018/0323060 A1
(43) Pub. Date: Nov. 8, 2018

(54) SUBSTRATE PROCESSING METHOD, SUBSTRATE PROCESSING APPARATUS, SUBSTRATE PROCESSING SYSTEM AND RECORDING MEDIUM

(71) Applicant: Tokyo Electron Limited, Tokyo (JP)

(72) Inventor: Yuji Katagiri, Koshi-shi, Kumamoto (JP)

(21) Appl. No.: 15/770,865

(22) PCT Filed: Oct. 17, 2016
(86) PCT No.: PCT/JP2016/080742

§ 371 Date: Apr. 25, 2018

(30) Foreign Application Priority Data
Oct. 28, 2015 (JP) 2015-211845

(51) Int. Cl. H01L 21/02; H01L 21/67

(52) U.S. Cl. CPC H01L 21/02063; H01L 21/76802; H01L 21/67069; H01L 21/67023

(57) ABSTRACT

A substrate after being subjected to a dry etching processing is prepared. Then, an ultraviolet ray having a preset peak wavelength among multiple peak wavelengths is irradiated to the substrate based on a gas used in the dry etching processing.

### TECHNICAL FIELD

The various embodiments described herein pertain generally to a substrate processing method, a substrate processing apparatus, a substrate processing system and a recording medium.

### BACKGROUND ART

Conventionally, a dry etching processing is performed on a substrate such as a semiconductor wafer. Since a polymer residue is attached to a surface of the substrate after being subjected to the dry etching processing, the substrate is cleaned with a polymer removing liquid. In this regard, a cleaning effect by the polymer removing liquid needs to be further improved.

For example, it is described in Patent Document 1 that the polymer residue on the substrate is decomposed by irradiating an ultraviolet ray of a preset wavelength to the substrate after being subjected to the dry etching processing from a UV lamp, and a chemical for wet processing is then supplied. Accordingly, as compared to a case in which only the chemical is supplied to the substrate, the cleaning effect is expected to be improved. The present inventors, however, have found out that even if the ultraviolet ray of the preset wavelength described in Patent Document 1 is irradiated to the substrate, the polymer residue may not be sufficiently decomposed.

### PRIOR ART DOCUMENT

Patent Document 1: Japanese Patent Laid-open Publication No. 2003-332313

### Problems to be Solved by the Invention

In view of the foregoing, exemplary embodiments provide a substrate processing method, a substrate processing apparatus and a substrate processing system capable of sufficiently removing a polymer residue adhering to a substrate after being subjected to a dry etching processing, and a recording medium therefor.

### DISCLOSURE OF THE INVENTION

In an exemplary embodiment, there is provided a substrate processing method comprising preparing a substrate after being subjected to a dry etching processing; and irradiating an ultraviolet ray having a preset peak wavelength to the substrate based on a gas used in the dry etching processing.

In another exemplary embodiment, there is provided a substrate processing apparatus comprising a UV irradiation unit configured to irradiate an ultraviolet ray having a preset peak wavelength to a substrate after being subjected to a dry etching processing based on a gas used in the dry etching processing.

According to the exemplary embodiments, a polymer residue adhering to a substrate after being subjected to a dry etching processing can be sufficiently removed.

### BRIEF DESCRIPTION OF THE DRAWINGS

FIG. 1 is a schematic cross sectional view illustrating a wafer (substrate) after being subjected to a dry etching processing, which is used in a substrate processing method according to exemplary embodiments.

FIG. 2 is a schematic configuration view illustrating a substrate processing system according to a first exemplary embodiment.

FIG. 3 is a schematic plan view illustrating a first processing apparatus (first substrate processing apparatus) of the substrate processing system according to the first exemplary embodiment.

FIG. 4 is a schematic plan view illustrating a second processing apparatus (second substrate processing apparatus) of the substrate processing system according to the first exemplary embodiment.

FIG. 5 is a schematic cross sectional view illustrating a dry etching unit of the substrate processing system according to the first exemplary embodiment.

FIG. 6 is a schematic cross sectional view illustrating a processing unit of the substrate processing system according to the first exemplary embodiment.

FIG. 7 is a schematic cross sectional view illustrating a UV processing chamber (substrate processing chamber) of the substrate processing system according to the first exemplary embodiment.

FIG. 8 is a flowchart for describing a substrate processing method according to the first exemplary embodiment.

FIG. 9 is a graph showing light absorption characteristics of polymer films depending on the kinds of an etching gas.

FIG. 10 is a schematic cross sectional view illustrating a modification example of the UV processing chamber (substrate processing chamber).

FIG. 11 is a schematic configuration view illustrating a substrate processing system according to a second exemplary embodiment.

FIG. 12 is a schematic configuration view illustrating a substrate processing system according to a third exemplary embodiment.

FIG. 13 is a schematic configuration view illustrating a substrate processing system according to a fourth exemplary embodiment.

### DETAILED DESCRIPTION

### First Exemplary Embodiment

Hereinafter, a first exemplary embodiment will be described with reference to FIG. 1 to FIG. 10.

<Structure of Substrate>

First, a wafer (substrate) after being subjected to a dry etching processing, which is used in a substrate processing method according to the present exemplary embodiment, will be explained with reference to FIG. 1.

FIG. 1 illustrates the wafer (substrate) W after being subjected to a dry etching processing. The wafer W has a wiring layer 91, a liner film 92 and an interlayer insulating film 93, which are deposited on top of each other. The liner film 92 is formed on the wiring layer 91, the interlayer insulating film 93 is formed on the liner film 92. A Cu wiring 94 as an example of a metal wiring is formed in the wiring layer 91.

Further, the wafer W has a via hole 95. The via hole 95 is formed by dry etching. The via hole 95 reaches the wiring layer 91 through the interlayer insulating film 93, and a surface of the Cu wiring 94 is exposed from a bottom of the via hole 95.

Further, a polymer residue P remains on a surface of the wafer W. This polymer residue P grows as a residue of a gas used in the dry etching reacts with moisture or oxygen in the atmosphere. Further, the polymer residue P has different compositions depending on the kinds of the gas used in the dry etching.

<Configuration of Substrate Processing System>

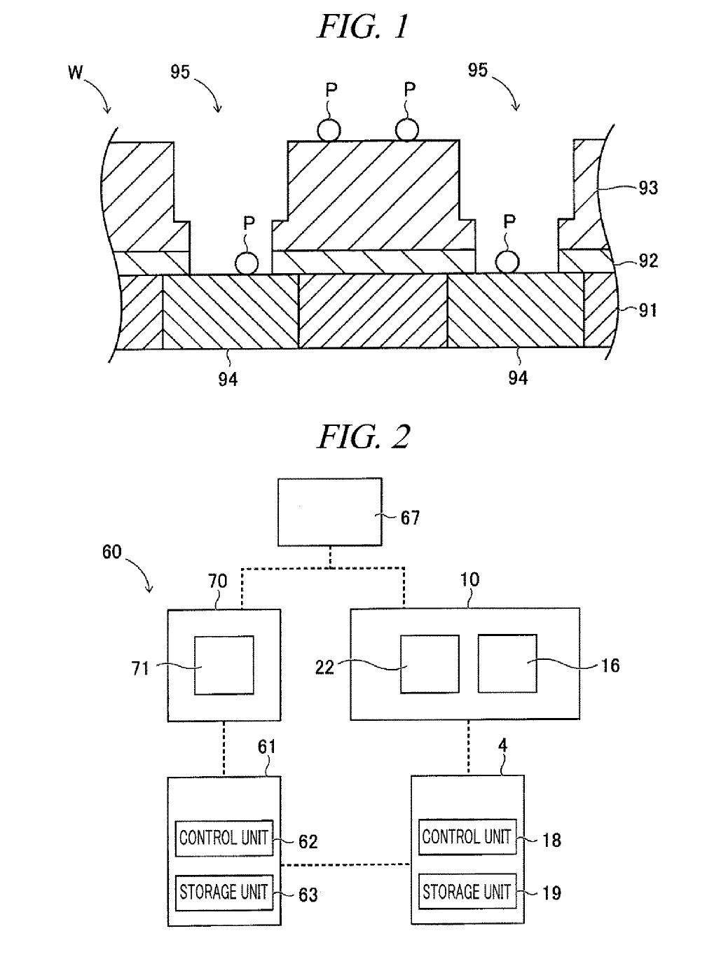

Now, a configuration of a substrate processing system configured to perform the substrate processing method according to the present exemplary embodiment will be explained with reference to FIG. 2. FIG. 2 is a diagram illustrating a schematic configuration of the substrate processing system according to the present exemplary embodiment.

As depicted in FIG. 2, a substrate processing system 60 according to the present exemplary embodiment is equipped with a first processing apparatus (first substrate processing apparatus) 70 as a pre-processing apparatus; and a second processing apparatus (second substrate processing apparatus 10) as a post-processing apparatus. Further, the substrate processing system 60 includes a first control device 61 configured to control the first processing apparatus 70; and a second control device 4 configured to control the second processing apparatus 10.

The first processing apparatus 70 is implemented by a dry etching apparatus, and equipped with a dry etching unit 71 configured to perform a dry etching processing on the wafer W. Further, the second processing apparatus 10 is implemented by a wet processing apparatus, and is equipped with a UV processing chamber 22 configured to irradiate an ultraviolet ray to the wafer W on which the dry etching processing is performed in the first processing apparatus 70 and a processing unit 16 configured to perform a cleaning processing on the wafer W to which the ultraviolet ray is irradiated in the UV processing chamber 22.

The first control device 61 is implemented by, for example, a computer, and includes a control unit 62 and a storage unit 63. The storage unit 63 is implemented by a storage device such as, but not limited to, a RAM (Random Access Memory), a ROM (Read Only Memory) or a hard disk, and stores therein programs for controlling various kinds of processings performed in the first processing apparatus 70. The control unit 62 is, for example, a CPU (Central Processing Unit), and controls an operation of the first processing apparatus 70 by reading and executing the programs stored in the storage unit 63.

The second control device 4 is implemented by, for example, a computer, and includes a control unit 18 and a storage unit 19. The storage unit 19 is implemented by, but not limited to, a RAM, a ROM or a hard disk, and stores therein programs for controlling various kinds of processings performed in the second processing apparatus 10. The control unit 18 is implemented by, for example, a CPU, and controls an operation of the second processing apparatus 10 by reading and executing the programs stored in the storage unit 19.

Further, these programs are recorded in a computer-readable recording medium, and may be installed to the storage unit 63 of the first control device 61 or the storage unit 19 of the second control device 4 from the recording medium.

The first control device 61 and the second processing apparatus 10 are connected to a host control device 67. The host control device 67 is implemented by, for example, a computer, and controls the entire substrate processing system 60 including the first control device 61 and the second processing apparatus 10.

<Configuration of First Processing Apparatus>

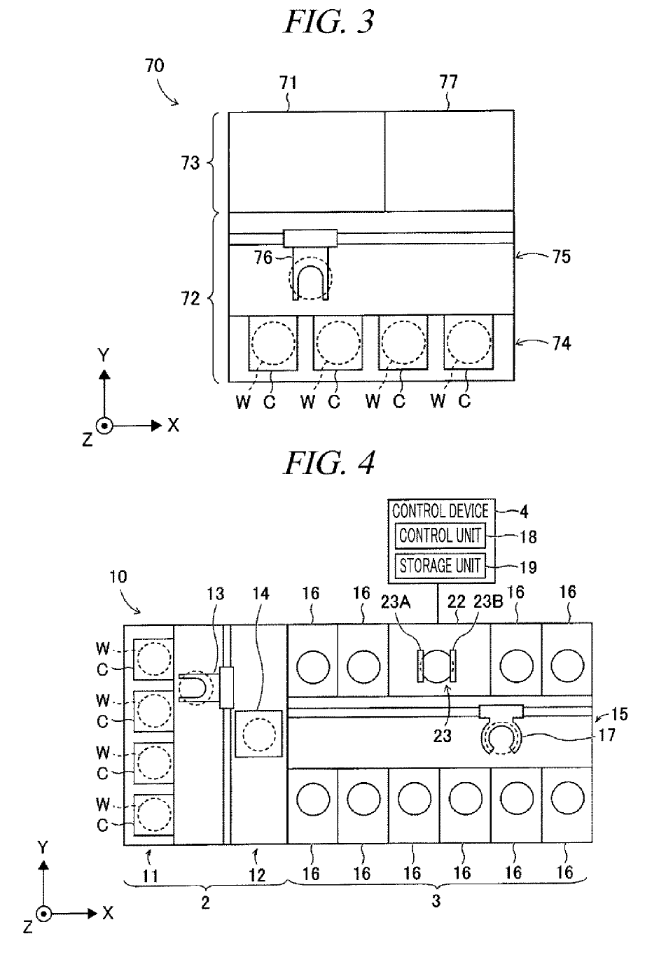

Now, a configuration of the first processing apparatus (first substrate processing apparatus) 70 will be explained with reference to FIG. 3. FIG. 3 is a diagram illustrating a schematic configuration of the first processing apparatus 70. In the following, in order to clarify positional relationships, the X-axis, Y-axis and Z-axis which are orthogonal to each other will be defined, and the positive Z-axis direction will be regarded as a vertically upward direction.

As depicted in FIG. 3, the first processing apparatus 70 includes a carry-in/out station 72 and a processing station 73. The carry-in/out station 72 and the processing station 73 are provided adjacent to each other.

The carry-in/out station 72 is provided with a placing section 74 and a transfer section 75. In the placing section 74, a plurality of carriers C is placed to accommodate a plurality of wafers W horizontally.

The transfer section 75 is provided adjacent to the placing section 74, and a substrate transfer device 76 is provided within the transfer section 75. The substrate transfer device 76 is provided with a wafer holding mechanism configured to hold the wafer W. Further, the substrate transfer device 76 is movable horizontally and vertically and pivotable around a vertical axis, and transfers the wafers W between the carriers C and the processing station 73 by using the wafer holding mechanism.

To elaborate, the substrate transfer device 76 takes out the wafer W from the carrier C placed in the placing section 74 and carries the taken wafer W into the dry etching unit 71 of the processing station 73 to be described later. Further, the substrate transfer device 76 also takes out the wafer W from a load lock chamber 77 of the processing station 73 to be described later and carries the taken wafer W back into the carrier C in the placing section 74.

The processing station 73 is provided adjacent to the transfer section 75. The processing station 73 is equipped with the dry etching unit 71 and the load lock chamber 77.

The dry etching unit 71 is configured to perform, an example of a pre-processing, the dry etching processing on the wafer W carried thereinto by the substrate transfer device 76. Accordingly, the via hole 95 is formed in the wafer W, and the Cu wiring 94 (see FIG. 1) within the wafer W is exposed.

The dry etching processing is performed in a decompressed state. Further, in the dry etching unit 71, an aching processing of removing an unnecessary resist may be performed after the dry etching processing.

The load lock chamber 77 is configured such that a pressure of an inside thereof is switchable between an atmospheric state and a decompressed state. The load lock chamber 77 is provided with a non-illustrated substrate transfer device. The wafer W after being subjected to the dry etching processing in the dry etching unit 71 is carried out of the dry etching unit 71 by the non-illustrated substrate transfer device of the load lock chamber 77, and then carried out by the substrate transfer device 76.

To elaborate, the inside of the load lock chamber 77 is maintained in the decompressed state until the wafer W is carried out from the dry etching unit 71. After the carrying-out of the wafer W is completed, an inert gas such as nitrogen or argon is supplied into the load lock chamber 77, so that the inside of the load lock chamber 77 is turned into the atmospheric state. After the load lock chamber 77 is turned into the atmospheric state, the substrate transfer device 76 carries out the wafer W.

Accordingly, the wafer W after being subjected to the dry etching processing is accommodated in the carrier C by the substrate transfer device 76, and then, is transferred into the second processing apparatus 10.

<Configuration of Second Processing Apparatus>

Now, a configuration of the second processing apparatus (second substrate processing apparatus) 10 will be explained with reference to FIG. 4. FIG. 4 is a diagram illustrating a schematic configuration of the second processing apparatus 10.

FIG. 4 is a diagram illustrating a schematic configuration of the second processing apparatus according to the present exemplary embodiment. In the following, in order to clarify positional relationships, the X-axis, Y-axis and Z-axis which are orthogonal to each other will be defined, and the positive Z-axis direction will be regarded as a vertically upward direction.

As depicted in FIG. 4, the second processing apparatus 10 includes a carry-in/out station 2 and a processing station 3. The carry-in/out station 2 and the processing station 3 are provided adjacent to each other.

The carry-in/out station 2 is provided with a carrier placing section 11 and a transfer section 12. In the carrier placing section 11, a plurality of carriers C is placed to accommodate a plurality of wafers horizontally.

The transfer section 12 is provided adjacent to the carrier placing section 11, and provided with a substrate transfer device 13 and a delivery unit 14. The substrate transfer device 13 is provided with a wafer holding mechanism configured to hold the wafer W. Further, the substrate transfer device 13 is movable horizontally and vertically and pivotable around a vertical axis, and transfers the wafers W between the carriers C and the delivery unit 14 by using the wafer holding mechanism.

The processing station 3 is provided adjacent to the transfer section 12. The processing station 3 is provided with a transfer section 15, a plurality of processing units 16 and a UV processing chamber (substrate processing chamber) 22. The plurality of processing units 16 is arranged at both sides of the transfer section 15. The UV processing chamber 22 is provided at one side of transfer section 15.

The transfer section 15 is provided with a substrate transfer device 17 therein. The substrate transfer device 17 is provided with a wafer holding mechanism configured to hold the wafer W. Further, the substrate transfer device 17 is movable horizontally and vertically and pivotable around a vertical axis. The substrate transfer device 17 transfers the wafers W between the delivery unit 14 and the processing units 16 by using the wafer holding mechanism.

The processing units 16 perform a predetermined substrate processing on the wafers W transferred by the substrate transfer device 17. The UV processing chamber 22 is equipped with, as will be described later, a UV irradiation unit 23 configured to selectively irradiate ultraviolet rays having multiple peak wavelengths. The UV irradiation unit 23 includes a plurality of UV lamps 23A and 23B configured to irradiate ultraviolet rays having different peak wavelengths. The UV irradiation chamber 22 irradiates light of a preset peak wavelength to the wafer W by using the UV lamp 23A or 23B having a preset peak wavelength, selected from the UV lamps 23A and 23B.

Further, the second processing apparatus 10 is provided with the second control device 4 as described above. The second control device 4 is, for example, a computer, and includes a control unit 18 and a storage unit 19. The storage unit 19 stores a program that controls various processings performed in the second processing apparatus 10. The control unit 18 controls the operations of the second processing apparatus 10 by reading and executing the program stored in the storage unit 19.

Further, the program may be recorded in a computer-readable recording medium, and installed from the recording medium to the storage unit 19 of the second control device 4. The computer-readable recording medium may be, for example, a hard disc (HD), a flexible disc (FD), a compact disc (CD), a magnet optical disc (MO), or a memory card.

In the second substrate processing apparatus 10 configured as described above, the substrate transfer device 13 of the carry-in/out station 2 first takes out a wafer W from a carrier C placed in the carrier placing section 11, and then places the taken wafer W on the delivery unit 14. The wafer W placed on the delivery unit 14 is taken out from the delivery unit 14 and then carried into the UV processing chamber 22 by the substrate transfer device 17 of the processing station 3.

A UV (ultraviolet ray) is irradiated to the wafer W carried into the UV processing chamber 22 by the UV lamp 23A (or 23B) having a preset peak wavelength selected depending on a gas used in the dry etching processing. After the UV is irradiated in the UV processing chamber 22, the wafer W is taken out from the UV processing chamber 22 and then carried into the processing unit 16 by the substrate transfer device 17.

The wafer W carried into the processing unit 16 is processed by the processing unit 16, and then, carried out from the processing unit 16 and placed on the delivery unit 14 by the substrate transfer device 17. After the processing of placing the wafer W on the delivery unit 14, the wafer W returns to the carrier C of the carrier placing section 11 by the substrate transfer device 13.

<Configuration of Dry Etching Unit>

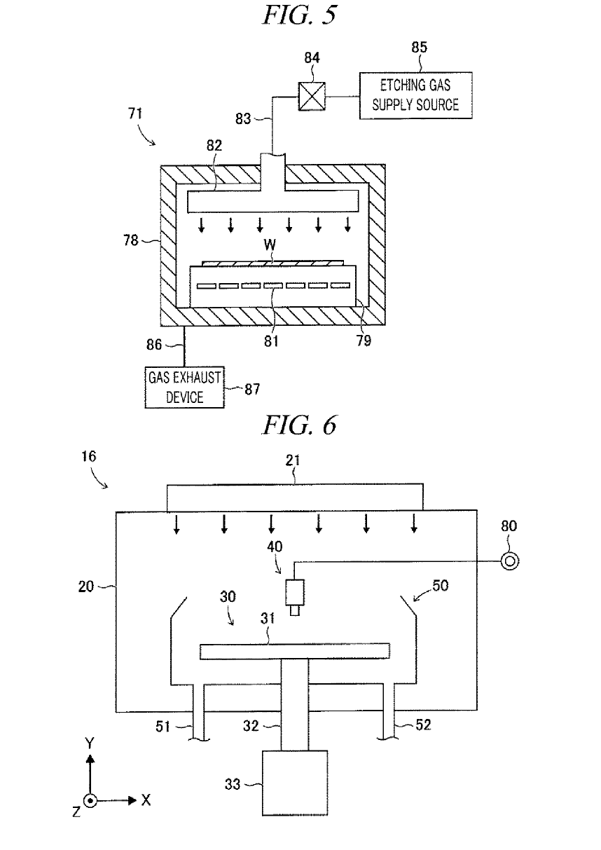

Now, a configuration of each unit of the first processing apparatus 70 and the second processing apparatus 10 will be explained. First, a configuration of the dry etching unit 71 of the first processing apparatus 70 will be discussed with reference to FIG. 5. FIG. 5 is a schematic diagram illustrating an example configuration of the dry etching unit 71.

As depicted in FIG. 5, the dry etching unit 71 is equipped with a hermetically sealed chamber 78 configured to accommodate the wafer W therein. Within the chamber 78, there is provided a placing table 79 on which the wafer W is placed horizontally. The placing table 79 is equipped with a temperature control mechanism 81 configured to adjust a temperature of the wafer W to a preset temperature by cooling or heating the wafer W. Provided at a sidewall of the chamber 78 is a carry-in/out opening (not shown) through which the wafer W is carried into/out of the chamber 78 with respect to the load lock chamber 77.

A shower head 82 is provided at a ceiling of the chamber 78. The shower head 82 is connected with a gas supply line 83. The gas supply line 83 is connected to an etching gas supply source 85 via a valve 84, and a preset etching gas is supplied to the shower head 82 from the etching gas supply source 85. The shower head 82 supplies the etching gas from the etching gas supply source 85 into the chamber 78.

Further, the etching gas supplied from the etching gas supply source 85 can be appropriately selected. By way of example, either a C₄F₈ gas or a C₄F₆ gas may be selectively used as the etching gas.

A gas exhaust device 87 is connected to a bottom of the chamber 78 via a gas exhaust line 86. A pressure of an inside of the chamber 78 is maintained in a decompressed state by the gas exhaust device 87.

The dry etching unit 71 is configured as described above, and performs the dry etching processing on the wafer W placed on the placing table 79 by supplying the etching gas into the chamber 78 from the shower head 82 in the state that the inside of the chamber 78 is decompressed by the gas exhaust device 87. As a result, the via hole 95 (see FIG. 1) is formed in the wafer W, so that the Cu wiring 94 is exposed.

Further, the dry etching unit 71 may further perform an aching processing of removing a resist film after performing the dry etching processing on the interlayer insulating film 93 (see FIG. 1) with the resist film as a mask, for example.

<Configuration of Processing Unit>

Now, a schematic configuration of the processing unit 16 of the second processing apparatus 10 will be discussed with reference to FIG. 6. FIG. 6 is a diagram illustrating the schematic configuration of the processing unit 16.

As depicted in FIG. 6, the processing unit 16 is equipped with a chamber 20, a substrate holding mechanism 30, a processing fluid supply unit 40 and a recovery cup 50.

The chamber 20 accommodates therein the substrate holding mechanism 30, the processing fluid supply unit 40 and the recovery cup 50. A fan filter unit (FFU) 21 is provided at the ceiling of the chamber 20. The FFU 21 forms a downflow in the chamber 20.

The substrate holding mechanism 30 is provided with a holding unit 31, a support unit 32 and a driving unit 33. The holding unit 31 holds the wafer W horizontally. The support unit 32 is a vertically extended member. A base end of the support unit 32 is rotatably supported by the driving unit 33, and the holding unit 31 is supported on a tip end of the support unit 32 horizontally. The driving unit 33 is configured to rotate the support unit 32 around a vertical axis. In this substrate holding mechanism 30, as the support unit 32 is rotated by using the driving unit 33, the holding unit 31 supported on the support unit 32 is rotated, so that the wafer W held by the holding unit 31 is rotated.

The processing fluid supply unit 40 supplies a processing fluid to the wafer W. The processing fluid supply unit 40 is connected to a processing fluid supply source 80.

The recovery cup 50 is disposed to surround the holding unit 31 and configured to collect the processing liquid scattered from the wafer W as the holding unit 31 is rotated. A liquid drain port 51 is formed at a bottom of the recovery cup 50. The processing liquid collected by the recovery cup 50 is drained to the outside of the processing unit 16 through the liquid drain port 51. Further, a gas exhaust opening 52 is also formed at the bottom of the recovery cup 50 to exhaust the gas supplied from the FFU 21 to the outside of the processing unit 16.

<Configuration of UV Processing Chamber>

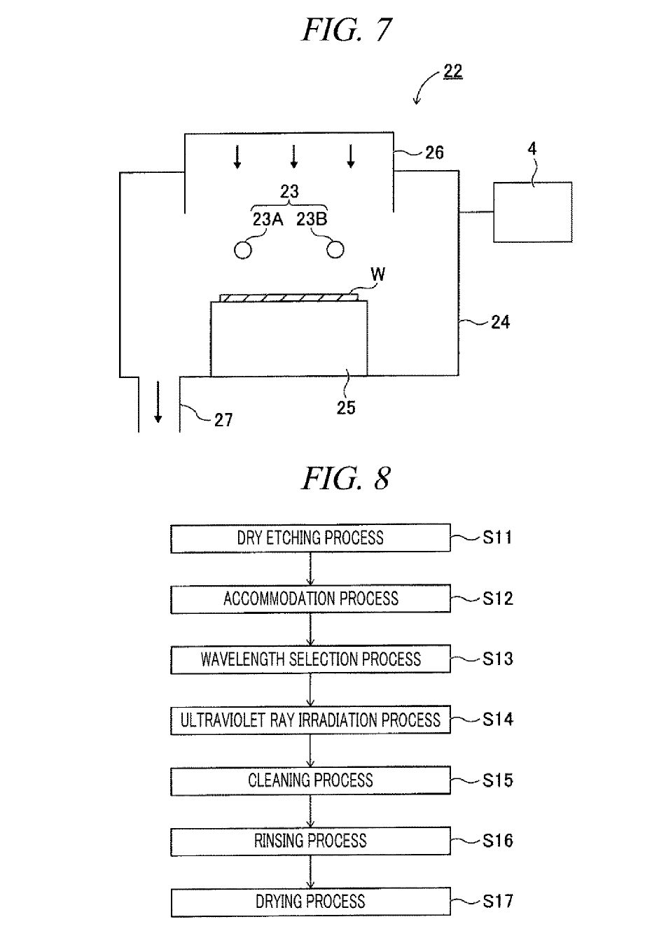

Now, a schematic configuration of the UV processing chamber (substrate processing chamber) 22 of the second processing apparatus 10 will be explained with reference to FIG. 7. FIG. 7 is a diagram illustrating the schematic configuration of the UV processing chamber 22.

As shown in FIG. 7, the UV processing chamber 22 is equipped with a chamber 24 configured to be decompressed; a substrate holding unit 25 provided within the chamber 24 and configured to hold the wafer W; and a UV irradiation unit 23 disposed at an upper portion of the chamber 24 and configured to irradiate ultraviolet rays in a vertically downward direction.

A gas inlet unit 26 configured to supply a processing gas such as an oxygen gas and a gas exhaust port 27 through which the gas is exhausted are connected to the chamber 24.

The UV irradiation unit 23 is configured to irradiate ultraviolet rays having different peak wavelengths selectively. In this case, the UV irradiation unit 23 is equipped with the plurality of (two in FIG. 7) UV lamps 23A and 23B configured to irradiate the ultraviolet rays having the different peak wavelengths. The peak wavelengths of the UV lamps 23A and 23B are in a range from 250 nm to 350 nm. In this case, one of the UV lamps 23A and 23B is selected from the UV lamps 23A and 23B. Then, by using this selected UV lamp 23A or 23B having the peak wavelength, the ultraviolet ray having the corresponding peak wavelength is irradiated to the wafer W.

In the present exemplary embodiment, the UV lamps 23A and 23B include the first UV lamp 23A having the peak wavelength ranging from 250 nm to 270 nm; and the second UV lamp 23B having the peak wavelength ranging from 290 nm to 320 nm. To elaborate, when selecting the UV lamp 23A or 23B, the first UV lamp 23A (having the peak wavelength of 250 nm to 270 nm) is selected when a gas kind for the dry etching processing is C₄F₆, whereas the second UV lamp 23B (having the peak wavelength of 290 nm to 320 nm) is selected when a gas kind for the dry etching processing is C₄F₈. Each of the UV lamps 23A and 23B may be implemented by, by way of non-limiting example, an excimer barrier lamp charged with a Xe₂ gas.

As stated above, as the UV irradiation unit 23 has the UV lamps 23A and 23B having the different peak wavelengths and these UV lamps 23A and 23B are switchably used, the UV processing chamber 22 can have a simple structure and can be made compact.

The UV processing chamber 22 is connected to the second control device 4 of the aforementioned second processing apparatus 10. As the UV processing chamber 22 is controlled by the second control device 4, various operations of the UV processing chamber 22 are controlled.

For example, one of the first UV lamp 23A and the second lamp 23B is selectively turned on by being controlled by the second control device 4.

<Specific Operation of Substrate Processing System>

Now, a specific operation of the substrate processing system 60 will be explained with reference to FIG. 8. FIG. 8 is a flowchart for describing a substrate processing method according to the present exemplary embodiment. Further, individual processes shown in FIG. 8 are performed under the control of the first control device 61 or the second control device 4.

In the substrate processing system 60 according to the present exemplary embodiment, a dry etching process (process S11) shown in FIG. 8 is performed in the first processing apparatus 70, and processes from an accommodation process (process S12) to a drying process (process S17) are performed in the second processing apparatus 10.

As illustrated in FIG. 8, a dry etching processing is first performed in the dry etching unit 71 (dry etching process, process S11). In this dry etching process, the dry etching unit 71 performs a dry etching on the wafer W. At this time, the preset etching gas is supplied into the chamber 78 from the shower head 82 of the dry etching unit 71, and the dry etching is performed on the wafer W placed on the placing table 79 (see FIG. 5). Here, the etching gas is appropriately selected depending on the wafer W. By way of example, the C₄F₈ gas or the C₄F₆ gas is selectively used as the etching gas. The selection of the etching gas is performed by the first control device 61 based on information previously stored in the storage unit 63 of the first control device 61. Through this dry etching processing, the Cu wiring 94 provided within the wafer W is exposed (see FIG. 1).

Subsequently, the wafer W after being subjected to the dry etching processing is carried out of the dry etching unit 71 and carried into the load lock chamber 77 by the non-illustrated substrate transfer device of the load lock chamber 77 (see FIG. 3). Then, the substrate transfer device 76 takes the wafer W from the load lock chamber 77, transfers the taken wafer W to the placing table 74, and then, accommodates the transferred wafer W in the carrier C placed on the placing table 74.

The wafer W accommodated in the carrier C is transferred into the carrier placing section 11 of the second processing apparatus 10 from the first processing apparatus 70. Thereafter, the wafer W is taken out from the carrier C by the substrate transfer device 13 (see FIG. 4) of the second processing apparatus 10 and accommodated in the UV processing chamber 22 via the delivery unit 14 and the substrate transfer device 17 in sequence (accommodation process, process S12).

In the UV processing chamber 22, the wafer W after being subjected to the dry etching processing is accommodated in the chamber 24 and held by the substrate holding unit 25 (see FIG. 7). The inside of the chamber 24 is maintained in a decompressed state, and the processing gas is introduced into the chamber 24 from the gas inlet unit 26.

Next, one of the UV lamps 23A and 23B is selected from the UV lamps 23A and 23B belonging to the UV irradiation unit 23 to irradiate the ultraviolet ray having the preset peak wavelength (wavelength selection process, process S13). Then, the selected UV lamp 23A or 23B is turned on, and the ultraviolet ray having the preset peak wavelength is irradiated to the wafer W accommodated in the UV processing chamber 22 from the corresponding UV lamp 23A or 23B (ultraviolet ray irradiation process, process S14).

In the present exemplary embodiment, the selection of the UV lamp 23A or 23B is performed based on the kind of the etching gas used in the dry etching processing. By way of example, if the kind of the etching gas used to etch the wafer W is C₄F₆, the first UV lamp 23A (having the peak wavelength of 250 nm to 270 nm) is selected, whereas if the kind of the etching gas is C₄F₈, the second UV lamp 23B (having the peak wavelength of 290 nm to 320 nm) is selected.

Further, the selection of the UV lamp 23A or 23B may be carried out as an operator checks the kind of the etching gas and manually operates the second control device 4 based on the checked kind of the etching gas. Alternatively, the first control device 61 or the host control device 67 may transmit information upon the kind of the etching gas used in the dry etching processing to the second control device 4, and the second control device 4 may select the UV lamp 23A or 23B automatically based on the received information upon the kind of the etching gas. In the latter case, the appropriate UV lamp 23A or 23B can be selected securely.

As stated above, the polymer residue P remains on the surface of the wafer W on which the dry etching processing is performed (see FIG. 1). By irradiating the ultraviolet ray to the polymer residue P from the UV lamp 23A or 23B, binding of organic materials constituting the polymer residue P may be broken, and the polymer residue P may be decomposed by ozone and an oxygen radical generated from oxygen. Accordingly, it is possible to easily remove the polymer residue P in a cleaning process to be described later.

That is, if the ultraviolet ray is irradiated to oxygen in the atmosphere, the ozone or the oxygen radical is generated from the oxygen. Since this ozone or oxygen radical has a strong oxidizing power, the ozone or oxygen radical decomposes the polymer residue P. Further, the ozone or oxygen radical combines with a free radical or an excited molecule of an organic compound generated from the polymer residue P to turn it into a volatile substance such as CO₂ or H₂O. Further, even if the polymer residue P is not volatilized, the polymer residue P becomes a hydrophilic group of an organic compound such as a carbonyl group or a carboxyl group, so that wettability to water is improved. Therefore, in the cleaning process, the polymer residue P can be easily removed.

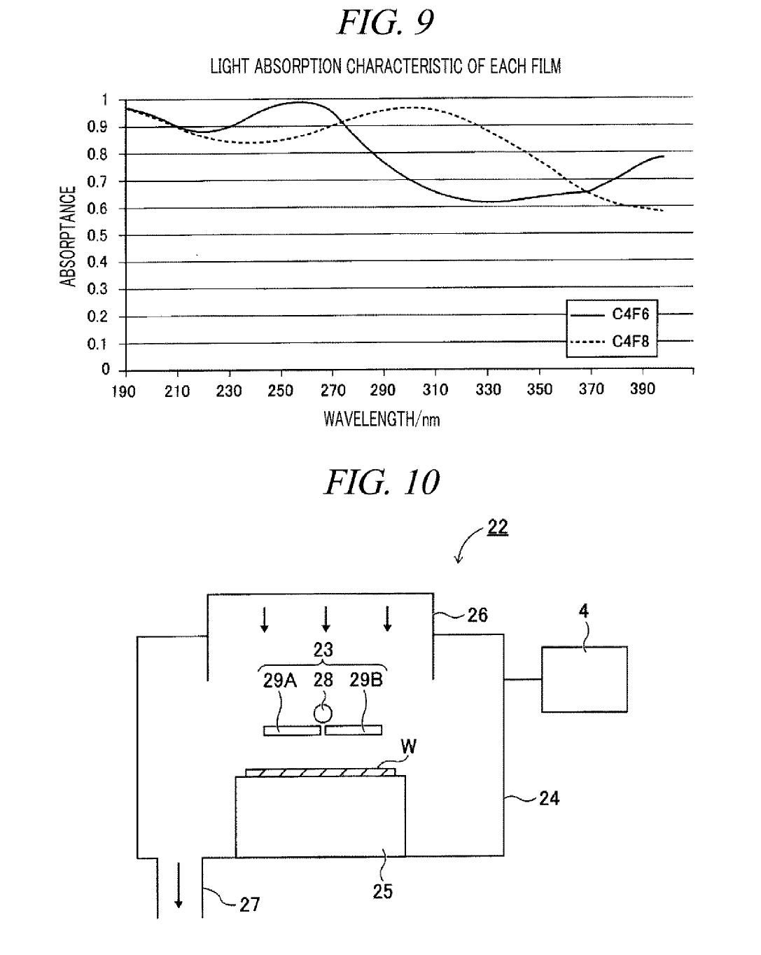

Here, however, it is found out that the polymer residue P has different properties depending on the kind of the gas used in the dry etching, and has different effective light absorption wavelength components. FIG. 9 is a graph showing light absorption characteristics of polymer films generated when using the etching gases (C₄F₆, C₄F₈) individually. As indicated by a solid line in FIG. 9, the polymer film generated by the C₄F₆ has the light absorption maximum near the wavelength of 250 nm to 270 nm. Meanwhile, as indicated by a dashed line in FIG. 9, the polymer film generated by the C₄F₈ has the light absorption maximum near the wavelength of 290 nm to 320 nm. For this reason, the ultraviolet ray having the peak wavelength in the range from 250 nm to 270 nm is irradiated to the polymer residue P when the dry etching gas is the C₄F₆, and the ultraviolet ray having the peak wavelength in the range from 290 nm to 320 nm is irradiated to the polymer residue P when the dry etching gas is the C₄F₈. Accordingly, the polymer residue P absorbs the ultraviolet ray efficiently, and the polymer residue P can be easily modified. As a result, the polymer residue P can be effectively removed with a cleaning liquid in the cleaning process to be described later.

The wafer W to which the ultraviolet ray is irradiated as stated above is then carried into the processing unit 16 by the substrate transfer device 17. In this processing unit 16, the cleaning processing (cleaning process, process S15) is performed. In this cleaning process, the wafer W is held by the substrate holding mechanism 30, and the substrate holding mechanism 30 rotates the wafer W around the vertical axis. Next, the processing fluid supply unit 40 (see FIG. 6) is placed above a central portion of the wafer W. Thereafter, the cleaning liquid is supplied from the processing fluid supply unit 40 to the wafer W at a controlled temperature and at a controlled flow rate. The cleaning liquid supplied to the wafer W is diffused on a main surface of the wafer W by a centrifugal force generated through the rotation of the wafer W. The cleaning liquid is scattered from the wafer W by the centrifugal force and then collected by the recovery cup 50. Thereafter, the cleaning liquid is drained from the recovery cup 50 to the outside of the processing unit 16 through the liquid drain port 51. Further, the cleaning liquid may be, by way of example, but not limitation, DHF, ammonium fluoride, hydrochloric acid, sulfuric acid, hydrogen peroxide, phosphoric acid, acetic acid, nitric acid, ammonium hydroxide, organic acid or an aqueous solution containing ammonium fluoride.

As stated above, the polymer residue P can be effectively removed by performing the cleaning process upon the wafer W to which the ultraviolet ray having the preset peak wavelength selected based on the dry etching gas is irradiated.

Then, in the processing unit 16, there is performed a rinsing processing of rinsing the main surface of the wafer W by supplying a rinse liquid such as DIW to the wafer W from the processing fluid supply unit 40 while rotating the wafer W (rinsing process, process S16). Accordingly, the cleaning liquid remaining on the surface of the wafer W or the polymer residue P floating in the cleaning liquid is removed from the wafer W along with the rinse liquid.

Further, upon the completion of the rinsing processing, the supply of the rinse liquid from the processing fluid supply unit 40 is stopped, and a drying processing of drying the wafer W is performed in the processing unit 16 (drying process, process S17). At this time, a rotation speed of the wafer W is increased for a preset time, so that the rinse liquid remaining on the main surface of the wafer W is scattered by the centrifugal force. Thereafter, the rotation of the wafer W is stopped.

Subsequently, the wafer W is taken out of the processing unit 16 by the substrate transfer device 17 (see FIG. 4) and accommodated in the carrier C placed in the carrier placing section 11 via the delivery unit 14 and the substrate transfer device 13 in sequence. Then, the series of the substrate processings upon the wafer W is completed.

According to the present exemplary embodiment as described above, the wafer W after being subjected to the dry etching processing is prepared, and this wafer W is accommodated in the UV processing chamber 22 having the UV irradiation unit 23 capable of irradiating the ultraviolet rays having the different peak wavelengths selectively. Then, the ultraviolet ray having the preset peak wavelength among the different peak wavelengths is selected based on the etching gas used in the dry etching processing, and this ultraviolet ray having the preset peak wavelength is irradiated to the wafer W. Accordingly, the polymer residue P caused by the corresponding etching gas absorbs the ultraviolet ray efficiently, so that the polymer residue P can be modified effectively. As a result, the polymer residue P can be effectively removed in the cleaning process.

The present exemplary embodiment has been described for the example case where the UV irradiation unit 23 of the UV processing chamber 22 is equipped with the UV lamps 23A and 23B configured to irradiate the ultraviolet rays having the different peak wavelengths. However, the exemplary embodiment is not limited thereto, and the UV irradiation unit 23 may be equipped with, as illustrated in FIG. 10, a single light source 28; and filters 29A and 29B which are allowed to be switched therebetween and provided between the light source 28 and the wafer W. These filters 29A and 29B are configured to irradiate ultraviolet rays having different peak wavelengths when light from the light source 28 passes through the corresponding filters 29A and 29B. In this configuration, as the light from the light source 28 passes through the single filter 29A or 29B selected from the filters 29A and 29B, an ultraviolet ray having a preset wavelength is irradiated to the wafer W. As stated, by switching the filters 29A and 29B automatically or manually, the ultraviolet rays having the different wavelengths can be selectively irradiated to the wafer W.

### Second Exemplary Embodiment

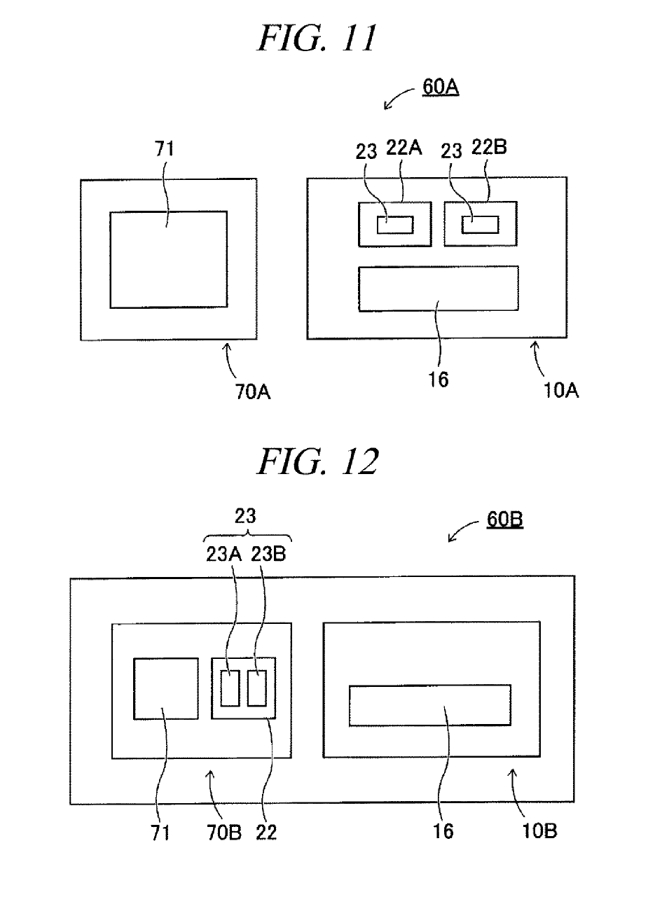

Now, referring to FIG. 11, a second exemplary embodiment will be discussed. FIG. 11 is a diagram illustrating a configuration of a substrate processing system configured to perform a substrate processing method according to the second exemplary embodiment. In FIG. 11, same parts as those descried in the first exemplary embodiment are assigned same reference numerals. Further, in the following, the description will be focused on distinctive features from the first exemplary embodiment, while redundant description is omitted.

In FIG. 11, a substrate processing system 60A is equipped with a first processing apparatus 70A as the pre-processing apparatus and a second processing apparatus 10A as the post-processing apparatus.

The first processing apparatus 70A is equipped with the dry etching unit 71 configured to perform the dry etching processing on the wafer W.

The second processing apparatus 10A is equipped with a plurality of (in the present exemplary embodiment, two) UV processing chambers (substrate processing chambers) 22A and 22B configured to irradiate ultraviolet rays to the wafer W after being subjected to the dry etching processing; and a processing unit 16 configured to perform the cleaning processing on the wafer W to which the ultraviolet ray is irradiated. The UV processing chambers 22A and 22B are configured to irradiate the ultraviolet rays having different peak wavelengths. To elaborate, each of the UV processing chambers 22A and 22B is provided with the UV irradiation unit 23 configured to irradiate the ultraviolet ray to the wafer W. The UV irradiation unit 23 (having the peak wavelength of 250 nm to 270 nm) of the UV processing chamber 22A and the UV irradiation unit 23 (having the peak wavelength of 290 nm to 320 nm) of the UV processing chamber 22B irradiate the ultraviolet rays having the different peak wavelengths. In this case, each of the UV irradiation units 23 of the UV processing chambers 22A and 22B is equipped with the UV lamp configured to irradiate the ultraviolet ray having the preset peak wavelength.

In the present exemplary embodiment, the wafer W after being subjected to the dry etching processing is transferred into the second processing apparatus 10A. Then, one of the UV processing chambers 22A and 22B is selected from the UV processing chambers 22A and 22B to accommodate the wafer W therein (wavelength selection process). In this case, the UV processing chamber 22A or 22B capable of irradiating the ultraviolet ray having the preset peak wavelength is selected based on the kind of the gas used in the dry etching processing. By way of example, if the dry etching gas is C₄F₆, the UV processing chamber 22A may be selected, whereas if the dry etching gas is C₄F₈, the UV processing chamber 22B may be selected. Then, the wafer W is accommodated in the selected UV processing chamber 22A or 22B.

Subsequently, the ultraviolet ray of the preset peak wavelength is irradiated to the wafer W from the UV irradiation unit 23 of the selected UV processing chamber 22A or 22B (ultraviolet ray irradiation process). Thereafter, the wafer W to which the ultraviolet ray is irradiated is carried into the processing unit 16, and the cleaning processing is performed therein (cleaning process).

The subsequent processes are the same as those described in the first exemplary embodiment.

As described above, by providing the UV processing chambers 22A and 22B capable of irradiating the ultraviolet rays having the different peak wavelengths, multiple wafers W after being subjected to the dry etching processing with different kinds of gases can be processed in the individual UV processing chambers 22A and 22B in parallel. Therefore, processing efficiency of the wafers W can be improved.

### Third Exemplary Embodiment

Now, referring to FIG. 12, a third exemplary embodiment will be discussed. FIG. 12 is a diagram illustrating a configuration of a substrate processing system configured to perform a substrate processing method according to the third exemplary embodiment. In FIG. 12, same parts as those descried in the first exemplary embodiment are assigned same reference numerals. Further, in the following, the description will be focused on distinctive features from the first exemplary embodiment, while redundant description is omitted.

In FIG. 12, a substrate processing system 60B is equipped with a first processing apparatus 70B as the pre-processing apparatus and a second processing apparatus 10B as the post-processing apparatus.

The first processing apparatus 70B is equipped with the dry etching unit 71 configured to perform the dry etching processing on the wafer W; and the UV processing chamber 22 configured to irradiate the ultraviolet ray to the wafer W after being subjected to the dry etching processing in the dry etching unit 71. The UV processing chamber 22 is equipped with the UV irradiation unit 23, and this UV irradiation unit 23 is configured to irradiate ultraviolet rays having different peak wavelengths selectively. The UV irradiation unit 23 has a plurality of UV lamps 23A and 23B having the different peak wavelengths, and these UV lamps 23A and 23B are used while being switched. By way of example, the UV lamp 23A may be set to have the peak wavelength ranging from 250 nm to 270 nm, and the UV lamp 23B may be set to have the peak wavelength ranging from 290 nm to 320 nm. Further, the UV processing chamber 22 may have the same configuration as that of the first exemplary embodiment. Alternatively, the processing chambers 22A and 22B capable of irradiating the ultraviolet rays having the different peak wavelengths may be provided instead of the UV processing chamber 22.

In the present exemplary embodiment, the wafer W after being subjected to the dry etching processing in the dry etching unit 71 is accommodated in the UV processing chamber 22 within the first processing apparatus 70B (accommodation process). Then, one of the UV lamps 23A and 23B is selected from the UV lamps 23A and 23B belonging to the UV irradiation unit 23 (wavelength selection process). In this case, the UV lamp 23A or 23B capable of irradiating the ultraviolet ray having the preset peak wavelength is selected based on the kind of the gas used in the dry etching processing. By way of example, if the dry etching gas is C₄F₆, the UV lamp 23A may be selected, whereas if the dry etching gas is C₄F₈, the UV lamp 23B may be selected. Then, the selected UV lamp 23A or 23B is turned on, and the ultraviolet ray having the preset peak wavelength is irradiated from this selected UV lamp 23A or 23B to the wafer W (ultraviolet ray irradiation process).

Thereafter, the wafer W to which the ultraviolet ray is irradiated is carried into the second processing apparatus 10B from the first processing apparatus 70B, and the cleaning processing is performed in the processing unit 16 of the second processing apparatus 10B (cleaning process). The subsequent processes are the same as those described in the first exemplary embodiment.

In the third exemplary embodiment, the polymer residue P adhering to the wafer W after being subjected to the dry etching processing can be sufficiently removed, the same as in the first exemplary embodiment.

Furthermore, the third exemplary embodiment is not anyway limiting, and the dry etching unit 71, the UV processing chamber 22 and the processing unit 16 may be accommodated in the single substrate processing apparatus (the first processing apparatus 70B or the second processing apparatus 10B).

### Fourth Exemplary Embodiment

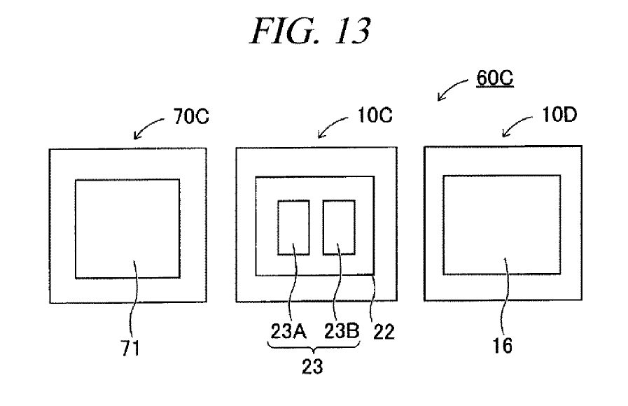

Now, referring to FIG. 13, a fourth exemplary embodiment will be described. FIG. 13 is a diagram illustrating a configuration of a substrate processing system configured to perform a substrate processing method according to the fourth exemplary embodiment. In FIG. 13, same parts as those descried in the first exemplary embodiment are assigned same reference numerals. Further, in the following, the description will be focused on distinctive features from the first exemplary embodiment, while redundant description is omitted.

In FIG. 13, a substrate processing system 60C is equipped with a first processing apparatus 70C, a second processing apparatus 10C, and a third processing apparatus 10D.

The first processing apparatus 70C is equipped with the dry etching unit 71 configured to perform the dry etching processing on the wafer W. Further, the second processing apparatus 10C is equipped with the UV processing chamber 22 configured to irradiate the ultraviolet ray to the wafer W after being subjected to the dry etching processing. Furthermore, the third processing apparatus 10D is equipped with the processing unit 16 configured to perform the cleaning processing on the wafer W to which the ultraviolet ray is irradiated in the UV processing chamber 22. The first processing apparatus 70C, the second processing apparatus 10C and the third processing apparatus 10D are configured as separate units.

The UV processing chamber 22 is equipped with the UV irradiation units 23, and these UV irradiation units 23 are configured to irradiate the ultraviolet rays having the different peak wavelengths selectively. Each UV irradiation unit 23 has a plurality of UV lamps 23A and 23B having the different peak wavelengths, and these UV lamps 23A and 23B are used while being switched. By way of example, the UV lamp 23A may be set to have the peak wavelength ranging from 250 nm to 270 nm, and the UV lamp 23B may be set to have the peak wavelength ranging from 290 nm to 320 nm. Further, the UV processing chamber 22 may have the same configuration as that of the first exemplary embodiment. Alternatively, the processing chambers 22A and 22B capable of irradiating the ultraviolet rays having the different peak wavelengths may be provided instead of the UV processing chamber 22.

In the present exemplary embodiment, the wafer W after being subjected to the dry etching processing in the dry etching unit 71 of the first processing apparatus 70C is carried into the second processing apparatus 10C from the first processing apparatus 70C. Then, the wafer W is accommodated in the UV processing chamber 22 (accommodation process). Thereafter, one of the UV lamps 23A and 23B having the preset peak wavelength is selected from the UV lamps 23A and 23B of the UV irradiation unit 23 (wavelength selection process). In this case, the UV lamp 23A or 23B capable of irradiating the ultraviolet ray having the preset peak wavelength is selected based on the kind of the gas used in the dry etching processing. By way of example, if the dry etching gas is C₄F₆, the UV lamp 23A may be selected, whereas if the dry etching gas is C₄F₈, the UV lamp 23B may be selected. Then, the selected UV lamp 23A or 23B is turned on, and the ultraviolet ray having the preset peak wavelength is irradiated from this selected UV lamp 23A or 23B to the wafer W (ultraviolet ray irradiation process).

Thereafter, the wafer W to which the ultraviolet ray is irradiated is carried into the third processing apparatus 10D from the second processing apparatus 10C, and the cleaning processing is performed in the processing unit 16 of the third processing apparatus 10D (cleaning process). The subsequent processes are the same as those described in the first exemplary embodiment.

In the fourth exemplary embodiment, the polymer residue P adhering to the wafer W after being subjected to the dry etching processing can be sufficiently removed, the same as in the first exemplary embodiment.

The present disclosure is not limited to the above-described exemplary embodiments themselves and constituent elements can be modified and changed in an embodiment within the scope of the present disclosure. Further, the constituent elements described in the above exemplary embodiments can be combined appropriately to form various inventions. By way of example, some constituent elements may be removed from the constituent elements shown in the exemplary embodiment and the constituent elements in the different exemplary embodiments may be combined appropriately.

We claim:

1. A substrate processing method, comprising:
preparing a substrate after being subjected to a dry etching processing; and
irradiating an ultraviolet ray having a preset peak wavelength to the substrate based on a gas used in the dry etching processing.

2. The substrate processing method of claim 1, further comprising:
supplying a cleaning liquid to the substrate after the irradiating of the ultraviolet ray having the preset peak wavelength.

3. The substrate processing method of claim 1, further comprising:
accommodating the substrate after being subjected to the dry etching processing into a substrate processing chamber equipped with a UV irradiation unit configured to irradiate ultraviolet rays having different peak wavelengths selectively.

4. The substrate processing method of claim 3,
wherein the UV irradiation unit comprises UV lamps configured to irradiate the ultraviolet rays having the different peak wavelengths, and
in the irradiating of the ultraviolet ray having the preset peak wavelength, a UV lamp configured to irradiate the ultraviolet ray having the preset peak wavelength is selected from the UV lamps, and the ultraviolet ray having the preset peak wavelength is irradiated to the substrate accommodated into the substrate processing chamber.

5. The substrate processing method of claim 3,
wherein the UV irradiation unit comprises a light source and filters allowed to be switched therebetween, and
the ultraviolet ray having the preset peak wavelength is irradiated to the substrate by allowing light from the light source to pass through one filter selected from the filters.

6. The substrate processing method of claim 3,
wherein the UV irradiation unit is configured to selectively irradiate the ultraviolet ray having the peak wavelength ranging from 250 nm to 270 nm and the ultraviolet ray having the peak wavelength ranging from 290 nm to 320 nm.

7. The substrate processing method of claim 6,
wherein, in the irradiating of the ultraviolet ray having the preset peak wavelength, the ultraviolet ray having the peak wavelength ranging from 250 nm to 270 nm is irradiated when the gas is C₄F₆, and the ultraviolet ray having the peak wavelength ranging from 290 nm to 320 nm is irradiated when the gas is C₄F₈.

8. The substrate processing method of claim 1, further comprising:
selecting one substrate processing chamber from substrate processing chambers configured to irradiate ultraviolet rays having different peak wavelengths; and
accommodating the substrate into the selected substrate processing chamber,
wherein, in the selecting of the one substrate processing chamber, a substrate processing chamber configured to irradiate the ultraviolet ray having the preset peak wavelength based on the gas used in the dry etching processing is selected.

9. A substrate processing apparatus, comprising:
a UV irradiation unit configured to irradiate an ultraviolet ray having a preset peak wavelength to a substrate after being subjected to a dry etching processing based on a gas used in the dry etching processing.

10. The substrate processing apparatus of claim 9,
wherein the UV irradiation unit comprises UV lamps selected based on the gas and configured to irradiate ultraviolet rays having different peak wavelengths.

11. The substrate processing apparatus of claim 9,
wherein the UV irradiation unit comprises a light source and filters allowed to be switched therebetween, and
the ultraviolet ray having the preset peak wavelength is irradiated to the substrate by allowing light from the light source to pass through one filter selected from the filters.

12. The substrate processing apparatus of claim 9,
wherein the UV irradiation unit is configured to selectively irradiate the ultraviolet ray having the peak wavelength ranging from 250 nm to 270 nm and the ultraviolet ray having the peak wavelength ranging from 290 nm to 320 nm.

13. The substrate processing apparatus of claim 9, further comprising:
substrate processing chambers configured to irradiate ultraviolet rays having different peak wavelengths,
wherein the UV irradiation unit is disposed in each of the substrate processing chambers.

14. The substrate processing apparatus of claim 9, further comprising:
a dry etching unit configured to perform the dry etching processing on the substrate.

15. The substrate processing apparatus of claim 9, further comprising:
a processing unit configured to perform a cleaning processing on the substrate to which the ultraviolet ray is irradiated in the UV irradiation unit.

16. The substrate processing apparatus of claim 9, further comprising:
a dry etching unit configured to perform the dry etching processing on the substrate; and
a processing unit configured to perform a cleaning processing on the substrate to which the ultraviolet ray is irradiated in the UV irradiation unit.

17. A substrate processing system, comprising:
a substrate processing apparatus as claimed in claim 14; and
a processing unit configured to perform a cleaning processing on the substrate to which the ultraviolet ray is irradiated in the UV irradiation unit.

18. A substrate processing system, comprising:
a dry etching unit configured to perform a dry etching processing on a substrate; and
a substrate processing apparatus as claimed in claim 15.

19. A substrate processing system, comprising:
a dry etching unit configured to perform a dry etching processing on a substrate;
a substrate processing apparatus as claimed in claim 9; and
a processing unit configured to perform a cleaning processing on the substrate to which the ultraviolet ray is irradiated in the UV irradiation unit.

20. A computer-readable recording medium having stored thereon computer-executable instructions that, in response to execution, cause a substrate processing apparatus to perform a substrate processing method as claimed in claim 1.
